(19) United States
(12) Patent Application Publication
(10) Pub. No.: US 2007/0207626 A1
(43) Pub. Date: Sep. 6, 2007

(54) Substrate processing method, semiconductor device and method for fabricating the semiconductor device

(75) Inventor: Masahiro Nishi, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Yamanashi (JP)

(21) Appl. No.: 11/712,987

(22) Filed: Mar. 2, 2007

(30) Foreign Application Priority Data
Mar. 3, 2006 (JP) 2006-057066

(51) Int. Cl. H01L 21/31

(52) U.S. Cl. 438/758

(57) ABSTRACT

A method for processing semiconductor includes: forming a first insulation film containing silicon on a surface of a GaN-base semiconductor layer; and removing the first insulation film formed on the surface of the GaN-base semiconductor layer. The composition ratio of Ga and N on the surface of the GaN-base semiconductor layer can be approximated to the stoichiometrical composition ratio.

### BACKGROUND OF THE INVENTION

1. Field of the Invention

This invention generally relates to a substrate processing method, a semiconductor device and a method for fabricating the semiconductor device, and more particularly, to a method for processing a substrate including a compound semiconductor layer including Ga and N, a semiconductor device including such a substrate, and a method for fabricating the semiconductor device.

2. Description of the Related Art

Attention to a semiconductor device using a compound semiconductor layer containing G and N (GaN-base semiconductor) has been drawn as a high-frequency, high-power amplifying element capable of operating at high frequencies and outputting high power and used for an amplifier for use in cellular phone base station. Such a semiconductor device may, for example, be an FET (Field Effect Transistor) such as a HEMT (High Electron Mobility Transistor). The GaN-base semiconductor may, for example, GaN, AlGaN or InGaN. AlGaN is a mixed crystal of GaN and AlN (aluminum nitride), and InGaN is a mixed crystal of GaN and InN (indium nitride). Further, there has been considerably activity in the development of an FET having GaN-base semiconductor (hereinafter, referred to as GaN-base FET) in order to realize further improved performance and reliability.

Japanese Patent Application Publication No. 2002-359256 discloses a GaN-base HEMT, which is one of GaN-base FETs. A conventional GaN-base HEMT has a sapphire substrate on which an electron traveling layer (buffer layer), an electron supply layer, and a protection layer (cap layer) are laminated in this order. A GaN-base semiconductor layer is composed of these layers. More specifically, the electron traveling layer is formed by a GaN layer, and the electron supply layer is formed by an AlGaN layer. The protection layer is formed by a GaN layer. A gate electrode, a source electrode and a drain electrode are formed on the GaN-base semiconductor layer. The source and drain electrodes are ohmic electrodes. An insulation film made of silicon nitride or the like is formed on the GaN-base semiconductor layer between the ohmic electrode and the gate electrode.

Leakage current may flow in the vicinity of the surface of the GaN-base semiconductor layer (or the interface with the insulation film) in the semiconductor device using the GaN-base semiconductor. Thus, in the GaN-base FET, increased OFF current (Ioff) and increased reverse current between the gate electrode and the ohmic electrode (for example, Igdo) may flow.

### SUMMARY OF THE INVENTION

The present invention has been made in view of the above circumstances, and has an object of providing a semiconductor processing method, a semiconductor device and its fabrication method capable of reducing leakage current in the proximity of the surface of the GaN-base semiconductor layer.

According to an aspect of the present invention, there is provided a method for processing semiconductor including: forming a first insulation film containing silicon on a surface of a GaN-base semiconductor layer; and removing the first insulation film formed on the surface of the GaN-base semiconductor layer. With this structure, Ga on the surface of the GaN-base semiconductor layer is diffused into the first insulation film. Thus, the composition ratio of Ga and N on the surface of the GaN-base semiconductor layer with Ga being rich can be approximated to the stoichiometrical composition ratio. It is thus possible to reduce leakage current on the surface of the GaN-base semiconductor layer.

The semiconductor may be made of one of silicon carbide, silicon, sapphire and gallium nitride. The GaN-base semiconductor may be a GaN layer or an AlGaN layer. The first insulation film may be one of a silicon nitride film, a silicon oxide film, and a silicon oxide nitride film.

According to another aspect of the present invention, there is provided a method for fabricating a semiconductor device including: forming a first insulation film containing silicon on a surface of the GaN-base semiconductor layer; forming a source electrode, a drain electrode and a gate electrode on the GaN-base semiconductor layer; and removing a part of the first insulation film between the source electrode and the drain electrode. With this structure, Ga on the surface of the GaN-base semiconductor layer between the source and drain electrodes is diffused into the first insulation film. Thus, the Ga-rich surface of the GaN-base semiconductor layer can be approximated to the stoichiometrical composition ratio. It is thus possible to restrain Ioff and Igdo of GaN-base FET and realize improved characteristics.

The method may further include removing the first insulation film formed on the surface of the GaN-base semiconductor layer. The first insulation film into which Ga has been diffused can be removed.

The method may further include forming a second insulation film on the surface of the GaN-base semiconductor layer from which the first insulation film has been removed. It is thus possible to further diffuse Ga on the surface of the GaN-base semiconductor layer into the second insulation film.

The GaN-base semiconductor layer may be a GaN layer or an AlGaN layer. The first insulation film may be one of a silicon nitride film, a silicon oxide film and a silicon oxide nitride film.

The second insulation film may contain no oxygen. The second insulation film may be a silicon nitride film.

According to yet another aspect of the present invention, there is provided a semiconductor device including: a GaN-base semiconductor layer formed on a substrate; source, drain and gate electrodes formed on the GaN-base semiconductor layer; a first insulation film provided so as to contact the GaN-base semiconductor layer between the source electrode and the drain electrode, the first insulation film having an opening and containing silicon; and a second insulation film provided so as to contact the GaN-base semiconductor layer in the opening. With this structure, Ga on the surface of the GaN-base semiconductor layer between the source electrode and the drain electrode is diffused into the first insulation film. Thus, the Ga-rich surface of the GaN-base semiconductor layer can be approximated to the stoichiometrical composition ratio. It is thus possible to restrain Ioff and Igdo of GaN-base FET and realize improved characteristics.

The first insulation film may be one of a silicon nitride film, a silicon oxide film and a silicon oxide nitride film. The substrate may be made of one of silicon carbide, silicon, sapphire, and gallium nitride. The GaN-base semiconductor layer may be one of a GaN layer and an AlGaN layer.

The second insulation film may contain no oxygen. The second insulation film may be a silicon nitride film. It is thus possible to prevent the surface of the GaN-base semiconductor layer from becoming Ga rich.

### BRIEF DESCRIPTION OF THE DRAWINGS

Other objects, features and advantages of the present invention will become more apparent from the following detailed description when read in conjunction with the accompanying drawings, in which:

FIGS. 1(a) through 1(d) are respectively cross-sectional views for describing a method of a semiconductor device in accordance with a first embodiment;

FIGS. 2(a) through 2(e) are respectively cross-sectional views for describing a method of a semiconductor device in accordance with a second embodiment (first half);

FIGS. 3(a) through 3(d) are respectively cross-sectional views for describing the method in accordance with the second embodiment (second half); and

FIGS. 4(a) through 4(d) are graphs for describing Ioff and Igdo of a GaN-base FET in accordance with the second embodiment.

### DESCRIPTION OF THE PREFERRED EMBODIMENTS

A description will be given, with reference to the accompanying drawings, of embodiments of the present invention.

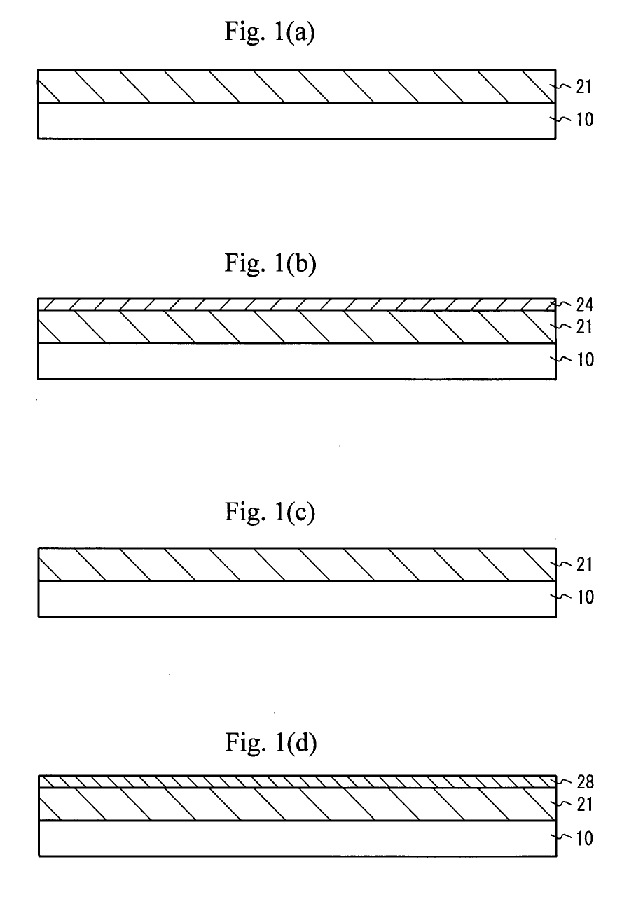

The inventors considered that the leakage current that flows in the proximity of the surface of a GaN-base semiconductor layer is caused by the presence of rich Ga on the surface of the GaN-base semiconductor layer. The inventors investigated the composition ratio of Ga and N on the surface of the GaN-base semiconductor layer. As shown in FIG. 1(a), a GaN-base semiconductor layer 21 having an uppermost layer of GaN was formed on a SiC (silicon carbide) substrate by MOCVD. Given process were applied to the structure shown in FIG. 1(a), and the composition ratio of Ga and N on the surface of the GaN layer was measured by an XPS (X-ray Photoelectron Spectroscopy) method. The results of the measurement are illustrated in Table 1.

TABLE 1

| Process | Composition ratio N/Ga |
|---|---|
| After GaN layer is formed | 0.66 |
| After thermal treatment (560° C.) | 0.53 |
| After SiN film is formed and removed | 0.62 |
| After thermal treatment (560° C.) | 0.76 |

The ratio N/Ga is equal to 0.66 while the stoichiometrical composition ratio is 1. This is because N on the surface of the GaN layer is drawn due to the condition for growth of the GaN layer and the thermal treatment applied to the GaN layer. In order to confirm the above, the GaN layer was annealed at 560° C. for 4 minutes by an RTA (Rapid Thermal Anneal) method. The ratio N/Ga on the surface of the GaN layer was 0.53. From the above fact, it is considered that N is drawn from the surface of the GaN layer and Ga becomes rich thereon due to the thermal treatment.

As shown in FIG. 1(b), after the thermal treatment at 560° C., a silicon nitride film 24 was deposited to a thickness of, for example, 100 nm on the GaN-base semiconductor layer 21 by, for example, plasma-assisted CVD. As shown in FIG. 1(c), the silicon nitride film 24 was removed by hydrofluoric acid. Thereafter, the ratio N/Ga on the surface of the GaN-base semiconductor layer 21 was 0.62. This means that the ratio N/Ga on the surface of the GaN-base semiconductor layer 21 is increased by growing and removing the silicon nitride film 24. It is considered that the above fact results from a mechanism in which Ga in the GaN layer is drawn to the silicon nitride film 24. Thus, the surface of the GaN layer approaches a condition such that N/Ga=1, which is the stoichiometrical composition ratio of GaN. Further, in FIG. 1(b), the silicon nitride film 24 was coated and was thermally treated or annealed at 350° C. for 30 minutes. Then, as shown in FIG. 1(c), the silicon nitride film 24 was removed and the ratio N/Ga was measured. A ratio of 0.76 was obtained. It is considered that the above ratio results from a mechanism in which the silicon nitride film 24 is annealed in the coated state, and Ga in the GaN-base semiconductor layer 21 is further diffused into the silicon nitride film 24.

In the method for processing the substrate in which the GaN-base semiconductor layer 21 is the uppermost layer in accordance with the first embodiment, as shown in FIG. 1(b), the silicon nitride film 24, which is defined as a first insulation film, is formed on the surface of the GaN-base semiconductor layer 21 formed on the substrate 10. Subsequently, as shown in FIG. 1(c), the silicon nitride film 24 on the surface of the GaN-base semiconductor layer 21 is removed. Thus, Ga on the surface of the GaN layer that is the uppermost layer of the GaN-base semiconductor layer 21 is diffused into the silicon nitride film 24. Thus, the composition ratio on the surface of GaN layer with Ga being rich can be approximated to the stoichiometrical composition ratio of GaN. After the process of FIG. 1(c), a GaN-base FET is formed. In the FET, leakage current at an interface between the GaN-base semiconductor layer 21 and the silicon nitride film 24 can be reduced. Similar advantages are provided by a second embodiment, which will be described later. In accordance with the method of the first embodiment, there is no need to form a mask because the silicon nitride film 24 is grown on the entire wafer, and is removed from the entire wafer. This reduces the fabrication cost.

It is preferable to perform the thermal treatment in a state in which the silicon nitride film 24 is provided. This facilitates further diffusion of Ga on the surface of the GaN-base semiconductor layer 21 into the silicon nitride film 24. Thus, the composition ratio on the surface of GaN layer with Ga being rich can be approximated to the stoichiometrical composition ratio of GaN. The temperature of the thermal treatment is not limited to 350° C. For example, at a higher temperature, Ga can be diffused into the silicon nitride film 24. The quantity of Ga to be diffused into the silicon nitride film 24 may be arbitrarily determined taking into consideration annealing temperature, time, thickness of the silicon nitride film, the type of the insulation film (silicon nitride film or another insulation film).

Particularly, Table 1 shows the following. The surface of the GaN-base semiconductor layer 21 is exposed and is thermally treated at a temperature of 550° C. or higher. Thus, the surface of the GaN-base semiconductor layer 21 with Ga being rich can be approximated to the stoichiometrical composition ratio of GaN by forming the silicon nitride film 24 on the GaN-base semiconductor layer 21 and annealing the GaN-base semiconductor layer 21 with the silicon nitride film 24 being provided thereon at 350° C. or higher.

The silicon nitride film 24 formed on the GaN-base semiconductor layer 21 is removed therefrom. It is thus possible to prevent Ga from being diffused from the Ga-diffused silicon nitride film 24 to the surface of the GaN-base semiconductor layer 21 again and to prevent the surface of the GaN-base semiconductor layer 21 from becoming rich.

Further, as shown in FIG. 1(d), a silicon nitride film 28 is formed on the surface of the GaN-base semiconductor layer 21 from which the silicon nitride film 24 has been removed. When Ga is diffused into the silicon nitride film 24 at some level, diffusion of Ga is restricted. In terms of the above fact, the silicon nitride film 24 is removed, and then, the new silicon nitride film 28 is formed. It is thus possible to diffuse Ga on the surface of the GaN-base semiconductor layer 21 into the silicon nitride film 28.

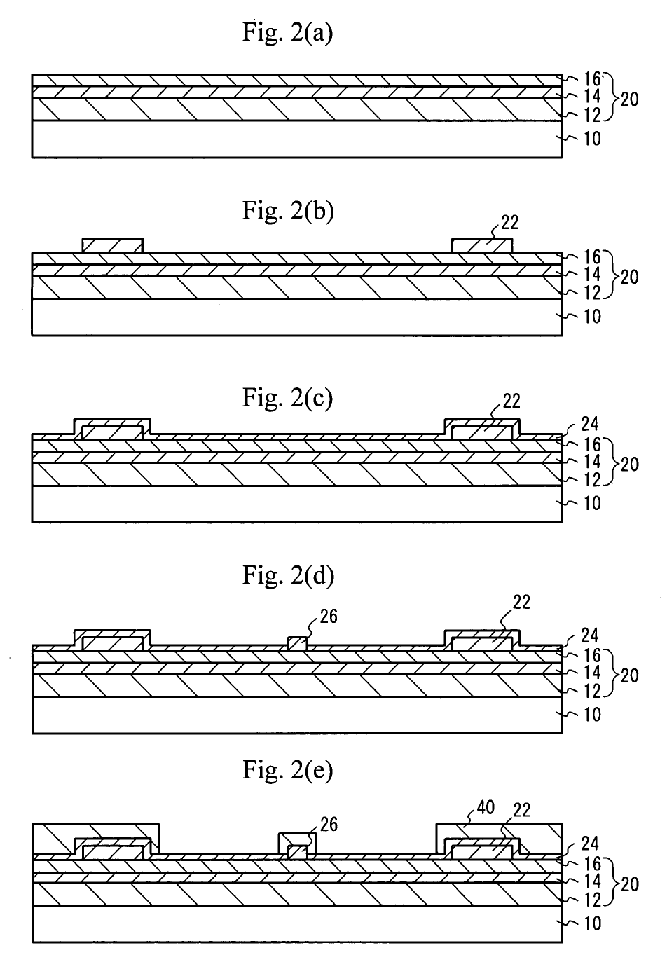

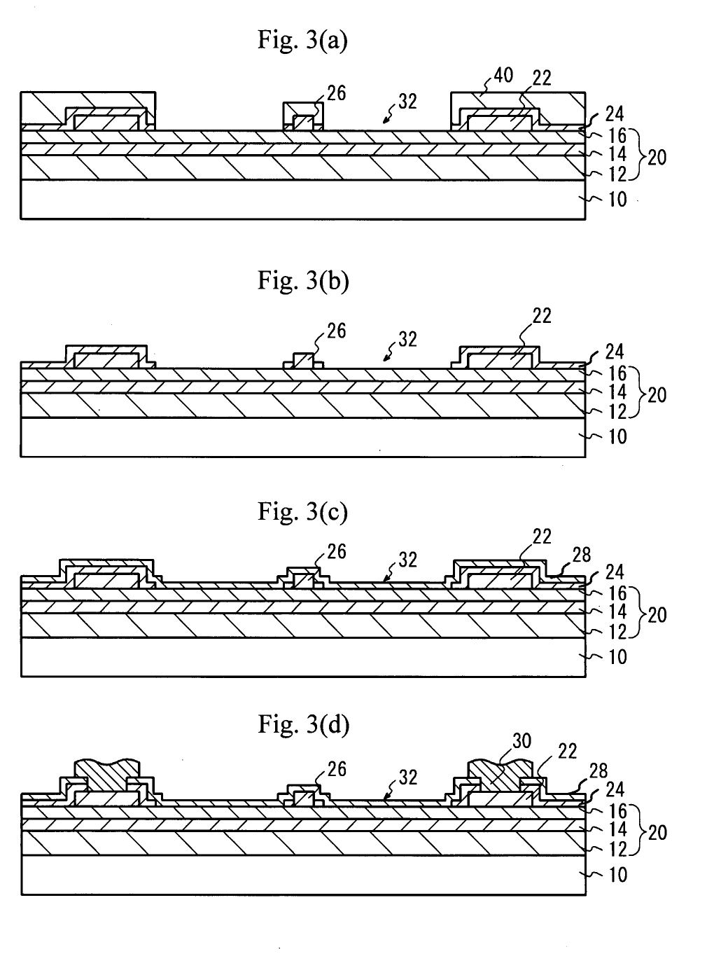

FIGS. 2(a) through 3(d) are respectively cross-sectional views for illustrating a method of fabricating a GaN-base HEMT in accordance with a second embodiment. A GaN-base semiconductor layer 20 is formed on the SiC substrate 10 by MOCVD. The GaN-base semiconductor layer 20 includes the GaN buffer layer 12, the AlGaN electron supply layer 14, and the GaN cap layer 16, which are formed in that order. The substrate may be a sapphire substrate or a GaN substrate. Referring to FIG. 2(b), ohmic electrodes 22 (source and drain electrodes) are formed on the GaN-base semiconductor layer 20 by, for example, a vapor deposition or liftoff process. The ohmic electrodes 22 may be a Ti/Au or Ti/Al structure. Referring to FIG. 2(c), the silicon nitride film 24 is formed to a thickness of 100 nm on the GaN-base semiconductor layer 20 and the ohmic electrodes 22 by, for example, plasma-assisted CVD. Then, a thermal treatment is performed at 350° C. for 30 minutes. Referring to FIG. 2(d), the silicon nitride film 24 is removed from a region in which a gate electrode 26 is to be formed. The gate electrode 26 may be formed on the GaN-base semiconductor layer 20 by the liftoff method and vapor deposition method in the form of Ni/Au or Ni/Al. Referring to FIG. 2(e), a photoresist 40 having openings between the gate electrode 26 and the ohmic electrodes 22 is formed on the silicon nitride film 24 and the gate electrode 26. The photoresist 40 covers the side surfaces of the gate electrode 26 in order to prevent the surfaces of the gate electrodes 26 from being etched, as will be described later with reference to FIG. 3(a).

Referring to FIG. 3(a), the silicon nitride film 24 is etched with the photoresist 40 being used as mask to thus form openings 32. The surface of the GaN-base semiconductor layer 20 is exposed through the openings 32. Referring to FIG. 3(b), the photoresist 40 is removed. Referring to FIG. 3(c), the silicon nitride film 28 (second insulation film) is deposited to a thickness of 200 nm on the GaN-base semiconductor layer 20 exposed through the openings 32 between the gate electrode 26 and the ohmic electrodes 22 and on the silicon nitride film 24 by, for example, plasma-assisted CVD. Referring to FIG. 3(d), openings are formed in the silicon nitride films 24 and 28 on the ohmic electrodes 22, and a wiring or interconnection layer 30 made of, for example, Au, is formed therein, so that the GaN-base HEMT can be completed in accordance with the second embodiment.

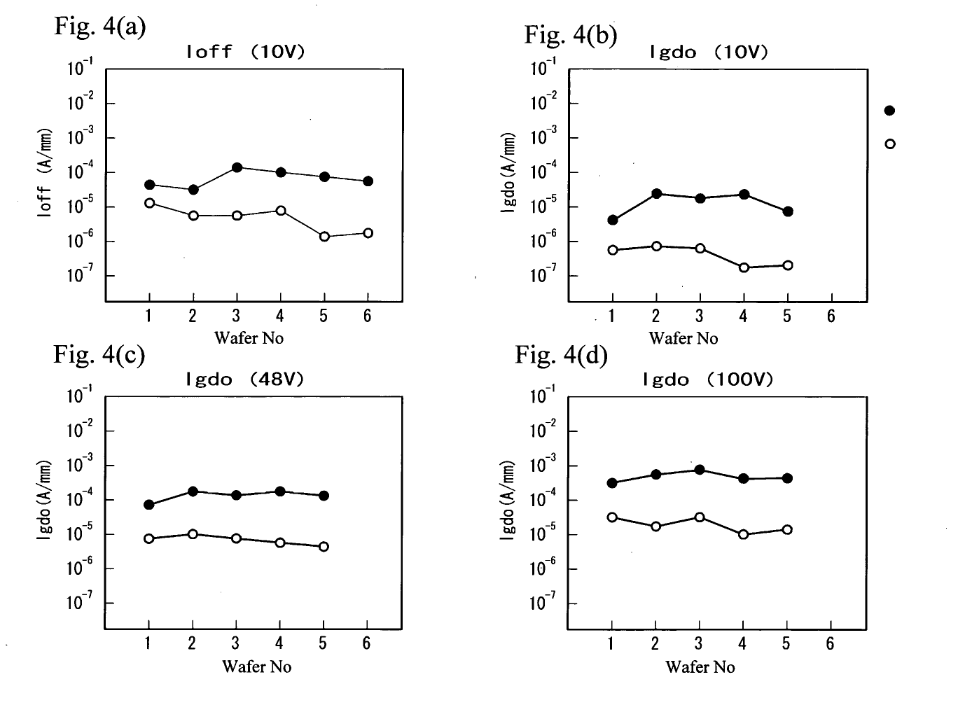

The inventors compared the electric characteristics of the GaN-base HEMT of the second embodiment with those of a conventional GaN-base HEMT (comparative example) fabricated without the processes shown in FIG. 2(e) to FIG. 3(c). FIG. 4(a) shows leakage currents (Ioff) at the time of pinch off for six wafers of the second embodiment and six wafers of the comparative example. The leakage current Ioff is a drain current at the time of pinch off per unit gate width (1 mm) for a drain voltage of 10 V. As shown in FIG. 4(a), the leakage current Ioff of the GaN-base HEMT of the second embodiment is one to two digits smaller than that of the comparative example.

FIGS. 4(b) through 4(d) show reverse currents (Igdo) that flow between the drain electrode and the gate electrode for five wafers of the second embodiment and five wafers of the comparative example. FIG. 4(b) shows the characteristics for a drain-gate voltage of 10 V, and FIG. 4(c) shows the characteristics for a drain-gate voltage of 48 V. FIG. 4(d) shows the characteristics for a drain-gate voltage of 100 V. The reverse currents Igdo for the different voltages of the GaN-base HEMT of the second embodiment are one to two digits smaller than those of the comparative example.

In the method for fabricating the GaN-base FET in accordance with the second embodiment, the silicon nitride film 24, which may be defined as a first insulation film, is formed on the surface of the GaN-base semiconductor layer 21. As shown in FIG. 2(b) and FIG. 2(d), the source and drain electrodes (ohmic electrodes) 22 and the gate electrode 26 are formed on the GaN-base semiconductor layer 21. As shown in FIG. 3(a), at least a part of the silicon nitride film 24 between the drain and source electrodes 22 (between the ohmic electrodes 22) is removed. Thus, Ga on the surface of the GaN-base semiconductor layer 20 between the gate electrode 26 and the ohmic electrodes 22 is diffused into the silicon nitride film 24. Therefore, when the surface of the GaN-base semiconductor layer 20 has rich Ga, the composition ratio of Ga and N approaches the stoichiometrical composition ratio. It is thus possible to restrict Ioff and Igdo of the GaN-base FET and realize improved characteristics.

Further, in the fabrication method in accordance with the second embodiment, as shown in FIG. 3(c), the silicon nitride film 28 (second insulation film) is formed on the surface of the GaN-base semiconductor layer 20 from which the silicon nitride film 24 has been removed. The GaN-base FET of the second embodiment has the silicon nitride film 24 (first insulation film) that is in contact with the GaN-base semiconductor layer 20 between the source electrode 22 and the drain electrode 22 and has the opening 32 provided in a part of the section between the source electrode 22 and the drain electrode 22. Further, the GaN-base FET has the silicon nitride film 28 (second insulation film) that contacts the GaN-base semiconductor layer 20 in the opening 32. When Ga is diffused into the silicon nitride film 24 at some level, diffusion of Ga is restricted. In terms of the above fact, the silicon nitride film 24 is removed, and then, the new silicon nitride film 28 is formed. It is thus possible to further diffuse Ga on the surface of the GaN-base semiconductor layer 21 into the silicon nitride film 28. The opening 32 may be provided at least between the source electrode and the gate electrode or between the drain electrode and the gate electrode. The leakage current associated with the opening 32 can be restricted.

Further, as shown in FIG. 2(c), the silicon nitride film 24 is formed on the GaN-base semiconductor layer 20, and is annealed. It is thus possible to further facilitate diffusion of Ga on the surface of the GaN-base semiconductor layer 20 into the silicon nitride film 24.

In the first and second embodiments, Ga is diffused into the silicon nitride film 24 serving as the first insulation film by the following mechanism. When the surface of the GaN-base semiconductor layer 21 with Ga being rich is exposed to the atmosphere, Ga is oxidized and an oxide of Ga is produced. When the silicon nitride film 24 is formed on the above GaN-base semiconductor layer 21, Si in the silicon nitride draws up the oxide of Ga. It is considered that the above phenomenon is caused by bonding of Si and O (oxide) in the Ga oxide. Thus, the first insulation film should be an insulation film containing silicon, and may be a silicon oxide film or a silicon oxide nitride film other than the silicon nitride film.

In the second embodiment, the silicon nitride film 28 is used as the second insulation film. If the second insulation film is formed by a film containing oxygen such as a silicon oxide film or a silicon oxide nitride film, oxygen and nitrogen on the surface of the GaN-base semiconductor layer 21 is likely to be bonded, so that the surface of the GaN-base semiconductor layer 21 becomes rich. Taking the above into account, preferably, the second insulation film does not contain oxygen. In other words, though the second insulation film may include oxygen, this oxygen is insufficient to form an oxide. Preferably, the second insulation film contains silicon.

The effects provided by the first and second embodiments are obtained as well for any GaN-base semiconductor layer containing Ga and N, which may, more specifically, be a GaN layer or AlGaN layer. The substrate 10 may be made of at least one of silicon, sapphire and gallium nitride other than SiC.

The present invention is not limited to the specifically described embodiments, but various variations and modifications may be made without departing from the scope of the present invention.

The present application is based on Japanese Patent Application No. 2006-057066 filed Mar. 3, 2006, the entire disclosure of which is hereby incorporated by reference.

What is claimed is:

1. A method for processing semiconductor comprising:
forming a first insulation film containing silicon on a surface of a GaN-base semiconductor layer; and
removing the first insulation film formed on the surface of the GaN-base semiconductor layer.

2. The method as claimed in claim 1, wherein the semiconductor comprises one of silicon carbide, silicon, sapphire and gallium nitride.

3. The method as claimed in claim 1, wherein the GaN-base semiconductor is a GaN layer or an AlGaN layer.

4. The method as claimed in claim 1 wherein the first insulation film is one of a silicon nitride film, a silicon oxide film, and a silicon oxide nitride film.

5. The method as claimed in claim 1, further comprising thermally treating the surface of the GaN-base semiconductor layer on which the first insulation film is provided at a temperature of 350° C. or higher.

6. A method for fabricating a semiconductor device comprising:
forming a first insulation film containing silicon on a surface of the GaN-base semiconductor layer;
forming a source electrode, a drain electrode and a gate electrode on the GaN-base semiconductor layer; and
removing a part of the first insulation film between the source electrode and the drain electrode.

7. The method as claimed in claim 6, further comprising forming a second insulation film on the surface of the GaN-base semiconductor layer from which the first insulation film has been removed.

8. The method as claimed in claim 6, further comprising forming a second insulation film on the surface of the GaN-base semiconductor layer from which the first insulation film has been removed.

9. The method as claimed in claim 6, wherein the GaN-base semiconductor layer is a GaN layer or an AlGaN layer.

10. The method as claimed in claim 6, wherein the GaN-base semiconductor layer is a GaN layer or an AlGaN layer.

11. The method as claimed in claim 6, wherein the first insulation film is one of a silicon nitride film, a silicon oxide film and a silicon oxide nitride film.

12. The method as claimed in claim 6, wherein the first insulation film is one of a silicon nitride film, a silicon oxide film and a silicon oxide nitride film.

13. The method as claimed in claim 7, wherein the second insulation film contains no oxygen.

14. The method as claimed in claim 8, wherein the second insulation film contains no oxygen.

15. The method as claimed in claim 7, wherein the second insulation film is a silicon nitride film.

16. The method as claimed in claim 8, wherein the second insulation film is a silicon nitride film.

17. A semiconductor device comprising:
a GaN-base semiconductor layer formed on a substrate;
source, drain and gate electrodes formed on the GaN-base semiconductor layer;
a first insulation film provided so as to contact the GaN-base semiconductor layer between the source electrode and the drain electrode, the first insulation film having an opening and containing silicon; and
a second insulation film provided so as to contact the GaN-base semiconductor layer in the opening.

18. The semiconductor device as claimed in claim 17, wherein the first insulation film is one of a silicon nitride film, a silicon oxide film and a silicon oxide nitride film.

19. The semiconductor device as claimed in claim 17, wherein the substrate is made of one of silicon carbide, silicon, sapphire, and gallium nitride.

20. The semiconductor device as claimed in claim 17, wherein the GaN-base semiconductor layer is one of a GaN layer and an AlGaN layer.

21. The semiconductor device as claimed in claim 17, wherein the second insulation film contains no oxygen.

22. The semiconductor device as claimed in claim 17, wherein the second insulation film is a silicon nitride film.
